(19) United States
(12) Patent Application Publication
(10) Pub. No.: US 2023/0380088 A1
(43) Pub. Date: Nov. 23, 2023

(54) EXPLOSION-PROOF HOUSING

(71) Applicant: SMA Solar Technology AG, Niestetal (DE)

(72) Inventor: Steffen Müller, Kassel (DE)

(21) Appl. No.: 18/358,325

(22) Filed: Jul. 25, 2023

Related U.S. Application Data
(63) Continuation of application No. PCT/EP2021/085675, filed on Dec. 14, 2021.

(30) Foreign Application Priority Data
Feb. 3, 2021 (DE) 10 2021 102 511.7

(51) Int. Cl. H05K 5/02; H02M 7/00; H05K 5/00; H05K 5/03; H05K 5/06

(52) U.S. Cl. CPC H05K 5/0221; H02M 7/003; H05K 5/0008; H05K 5/03; H05K 5/068

(57) ABSTRACT

An explosion-proof housing for a power electronics unit includes a housing pan and a cover that closes the housing pan via a seal, wherein the cover and the housing pan are pressed against each other at two opposing sides formed by edge regions of the cover and the housing pan via a plurality of fasteners that are configured to be released by rotation and that engage in latching structures. The plurality of fasteners are arranged in a central third of the respective sides. The explosion-proof housing can be used, for example, for a photovoltaic inverter.

### REFERENCE TO RELATED APPLICATIONS

This application is a Continuation of International Application number PCT/EP2021/085675, filed on Dec. 14, 2021, which claims the benefit of German Application number 10 2021 102 511.7, filed on Feb. 3, 2021. The contents of the above-referenced patent applications are hereby incorporated by reference in their entirety.

### FIELD

The disclosure relates to an explosion-proof housing, and also to a photovoltaic inverter having such a housing.

### BACKGROUND

In the case of power electronics units, for example, inverters for converting input power provided as direct current into an output power provided as alternating current, it is possible for an explosion of components, for example, capacitors or switching modules, to occur in the interior of housings of these devices, the possible explosion pressure of which is on the increase due to the continuous increase in power density resulting from technological development. The danger posed by this has been underestimated in the past. For this reason, only inadequate safety regulations currently exist for the design of housings for such devices, and cases have already been reported in which individuals who were in the vicinity of the device were injured by flying parts of the housing that broke loose due to an explosion.

A housing of such an electrical device must meet different normative requirements depending on the field of application. In particular, the housing can shield the interior of the device from its surroundings and, for example, close it in a dustproof and waterproof manner, with the result that the housing has an IP protection class according to DIN EN 60529 and/or corresponds to one of the NEMA protective classes according to NEMA Standard 250-2003. In addition, a housing may have to be able to pass further mechanical tests according to DIN and/or UL standards, for example, with regard to compression, impact testing, external influences such as bird strike and/or special exposure to water.

When handling high electrical powers using an electrical device, extremely high energy concentrations can accumulate in the housing of the device in a very short time. This may be desired, for example, in order to use capacitors or inductors for the temporary storage of electrical energy in the context of dynamic conversion from one form of current to another. However, undesirable energy concentrations can also occur, in particular in the event of a fault, maloperation, thermal overload or after aging processes. In these cases, electrical energy can be converted to a considerable extent into thermal and/or mechanical energy, for example, by components heating up strongly and exploding, or by flammable substances accumulating within a housing, for example, due to (electro-)chemical conversion processes, and being ignited by electrical flashovers, which in themselves are harmless.

As a result, a considerable overpressure can build up in the housing, which is sealed per se, of the electrical device. In the case of a power electronics converter, which has, for example, one of the usual protection classes IP44 or IP65, the overpressure can under unfavorable circumstances also build up very quickly, for example, within a few milliseconds. However, this should not lead to the housing being destroyed in an unpredictable manner, for example, by shattering uncontrollably and possibly fragments being flung out from the interior. In order to alleviate this problem, solutions exist whereby housings are designed in such a way that no housing parts detach even in the event of an explosion. In order not to have to produce unnecessarily sturdy and thus material-intensive housing designs, it appears advantageous to design housings such that in the event of an explosion a cover as the first housing component is able to detach in a controlled manner from a pan as the second housing component while a discharge gap forms, so that the explosion pressure can escape through the discharge gap. The gaps formed in this way are often too small, so that, in particular in the case of strong explosions, a sufficiently rapid pressure reduction cannot take place, and fastening elements which are actually intended to keep the housing components connected together fail.

In document DE 20 2020 101 874 U1, it is for this reason proposed that the cover be fastened to the pan by a plurality of screws in the edge region. The edge region of the cover has along one side a reinforcement which ensures that the cover in this region is in each case held on the pan by the screws, while on the other sides the screws are dimensioned such that they can detach in the event of an explosion, so that the reinforcement allows the cover to open as if hinged, but remains connected to the pan.

In document DE 10 2019 122 812 A1, it is alternatively proposed to fasten a housing cover using only a single, centrally arranged screw and to exert a sufficient sealing force on a circumferential seal arranged in the edge region of the cover. This central screw is dimensioned such that it reliably holds the cover even in the event of an explosion. However, the cover can deform in the edge region such that it lifts away from the pan and thus forms a discharge gap for the explosion pressure. However, the disadvantage of this solution is that the pan must have a centrally arranged, sufficiently mechanically sturdy counter-bearing for the screw, which is contrary to the desire for a compact design with low weight and easy installation.

Document DE 766456 C discloses an explosion-proof housing with sealing flanges for electrical devices, wherein, in the sealing flanges, rigid sealing means are provided between the housing and the cover.

### SUMMARY

The present disclosure is directed to a housing with a cover and a pan which permits a compact, lightweight construction with easy accessibility, and in which a detachment of housing components in the event of an explosion in the interior of the housing is reliably prevented.

According to one embodiment of the disclosure, an explosion-proof housing for a power electronic device comprises a housing pan and a cover closing the housing pan via a seal. The cover and the housing pan are pressed against each other using a plurality of fasteners that are configured to be released by rotation and that engage in latching structures on two opposite sides formed by edge regions of the cover and the housing pan. The plurality of fasteners are arranged in a central third of the respective sides. As a result, two outer regions of the cover are created adjacent to the central third which are not pressed against the seal by further fastening elements. Due to this arrangement of the fasteners, an explosion pressure can effectively act on these outer regions and can lever up the cover there, so that, in contrast to a conventional arrangement of fasteners even in the outer region, even at a reduced explosion pressure a discharge gap for the explosion pressure is formed between the cover and the housing pan as a result of the cover bending. The term “central third” is to be understood here to mean that the extension of this region along opposite sides comprises a maximum of one third of the side length and is smaller than or equal to the extension of the two adjacent outer regions in order to achieve the described leverage effect and thus a reliable bending of the cover to the desired extent in the event of an explosion.

In one embodiment, a circumferential seal can be arranged between the edges of the side walls of the housing pan and the cover. A compressive force is exerted on the seal by the fasteners via the cover. The achievable compressive force is dependent on the rigidity of the cover, which in one embodiment is configured in such a way that the compressive force is sufficient to make the housing closable over the entire sealing profile in accordance with a prespecified degree of protection. As a result, a degree of protection of the interior of the housing can be ensured of at least IP45, for example, at least IP65 and/or NEMA type 4X. In this case, due to the rigidity of the cover, it is possible and in the sense of the present disclosure desirable to provide, in each case, outer regions of the cover which are free of fasteners, in order to enable in the event of an explosion a reliable formation of a discharge gap by deformation of the cover in these outer regions, without fasteners opposing this deformation.

In one embodiment, on each side exactly one fastener is arranged in the middle of the side, so that two outer regions of equal size are formed in each case. As a result, a discharge gap can already form at a particularly low explosion pressure. Alternatively, two fasteners can be arranged on at least one side. As a result, an improved distribution of the contact pressure of the cover on the seal arranged between the cover and the housing pan can be achieved. One advantageous compromise between a uniform distribution of the contact pressure between the cover and the housing pan, on the one hand, and a minimum limit value of the explosion pressure, above which a discharge gap can form between the cover and the housing pan, is achieved when precisely two fasteners are provided on both sides, each fastener being arranged approximately at a third or two thirds of the side length, that is to say at opposite ends of the central third of the side in question.

The fasteners are, in one embodiment, located on those sides of the housing which are longer than the sides on which no fasteners are located in order to achieve a reduction in the limit value of the explosion pressure above which a discharge gap for the explosion pressure can form between the cover and the housing pan.

For the fasteners to be invisible on the front side of the housing, the fasteners can be arranged to be accessible from the housing pan side, and in each case engage in the latching structures which are arranged in or on the cover and are, in one embodiment, invisible on the side of the cover facing away from the housing pan.

In one embodiment, the fasteners are configured as screws and the latching structures are configured as threads, wherein the screws engage in the threads arranged in or on the cover through openings in the housing pan. The threads can be, in one embodiment, directly designed as an integral constituent part of the cover, or can be part of a fastening bar, which in turn is permanently connected, for example screwed, to the cover. Using a fastening bar enables the fastening bar in the event of a pressure rise in the housing interior to deform in such a way that a gap between the housing pan and the cover, through which the internal pressure can escape, also forms in a region of the fasteners.

In one embodiment, the fasteners are in each case configured as quarter-turn fasteners. Such a fastener can be released particularly easily simply by a rotation through 90° using a suitable tool, but alternatively even by hand and without a tool, and comprises a locking pin which engages in a latching structure formed as a retaining cam and is brought by the 90° rotation from a locked position into a free position in which the locking pin can be removed from the retaining cam. The retaining cam is, in one embodiment, configured as part of a fastening bar which is fastened to the cover at opposite ends and is shaped in a central region such that the retaining cam is spaced apart from the cover. The quarter-turn fastener should be captive. The quarter-turn fastener, in one embodiment, comprises a visually discernible indicator that shows a locking state of the quarter-turn fastener. The indicator can be formed, for example, by different colors or different characters on side faces of the quarter-turn fastener and indicate whether the quarter-turn fastener is in a locked position or a free position.

The latching structure can be configured as a spring-loaded retaining cam or even as a rigid retaining cam without a spring, in which case a spring-loaded locking pin is then used which has a disk spring, for example, which provides a holding force in the locked position of the locking pin in the retaining cam. Alternatively, the spring force can also be provided by the fastening bar itself if a disk spring or other additional spring element is dispensed with.

In order to adjust as desired the limit value for the explosion pressure, above which a discharge gap can form between the cover and the housing pan, the cover can have structural elements that reduce a forces required for the bending of the cover along a bending line running between the fasteners. For example, notches in the cover edge in the region of the fasteners, folds in the cover or a reduced cover thickness in the region of the bending line can be used to achieve this end. This facilitates bending or folding of the cover along the bending line, so that in the event of an explosion a discharge gap forms more rapidly and to a greater extent.

In one embodiment of the disclosure, a photovoltaic inverter is equipped with an explosion-proof housing as described above, as a result of which an inverter is formed in which, even in the event of an explosion in the interior of the inverter, no housing parts detach or at least housing parts which have detached remain in the interior space and are not hurled into the surroundings.

### BRIEF DESCRIPTION OF THE DRAWINGS

The disclosure is illustrated below with reference to the drawings, in which:

FIG. 1 shows an embodiment according to the disclosure of an explosion-proof housing in a front view,

FIG. 2 shows another embodiment according to the disclosure of an explosion-proof housing in a rear view,

FIG. 3 shows two detailed views of a fastener of a housing, and

FIG. 4 shows a cover with structural elements for reducing the forces required for forming a discharge gap.

### DETAILED DESCRIPTION

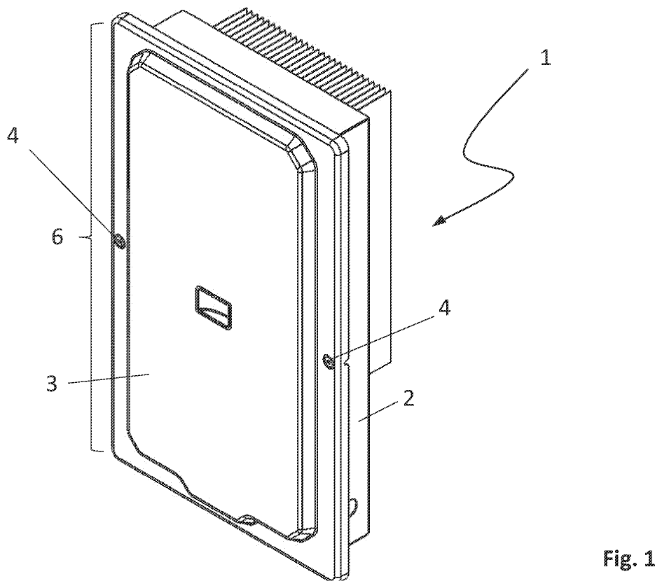

FIG. 1 shows a first embodiment according to the disclosure of an explosion-proof housing 1 of a power electronics unit. The housing comprises a housing pan 2, in the interior of which the device components are contained, and which is closed by a cover 3. A seal arranged between cover 3 and housing pan 2 prevents dirt and/or liquid from penetrating into the interior of the housing.

In one embodiment, the cover 3 is pressed against the housing pan 2 by two fasteners 4, the fasteners 4 being arranged centrally on opposite sides 6 of the rectangular housing 1. Further fastening elements with which the cover 2 is held on the housing pan 3 are not provided in the embodiment shown in FIG. 1. The sides on which the fasteners 4 are arranged are here longer than the sides with no fastener.

In one embodiment, the fasteners 4 can be formed by screws which are accessible from the cover side and engage in a thread in the housing pan 2. However, the screws can also be accessible from the side of the housing pan 2 and engage in threads arranged on or in the cover 3. The latter variant also perm its a design of the fastener 4 that is invisible from the cover side.

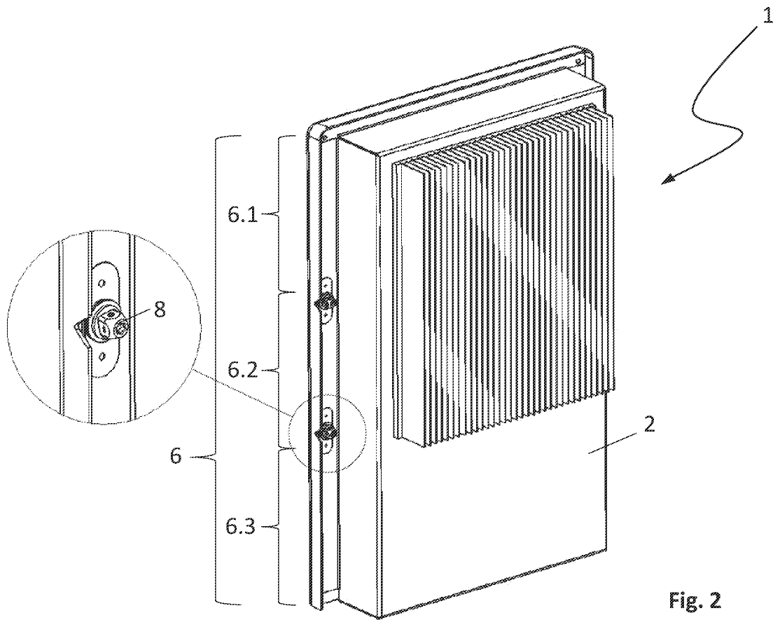

FIG. 2 shows another embodiment according to the disclosure of an explosion-proof housing 1 of a power electronics unit. Here, arranged on at least one side 6 of the housing 1, are two fasteners 4 which are located in the central third 6.2 of the length of the side 6. The adjacent two outer thirds 6.1 and 6.3 have no fasteners 4. Along the concealed side shown opposite the side 6, a single, central fastener or likewise two fasteners can be arranged at positions corresponding to the positions along the side 6.

As shown in the enlarged detail of FIG. 2, the fastener 4 is designed here as a quarter-turn fastener 8 which is accessible from the side of the housing pan 2. This makes it possible to release the cover 3 from the housing pan 2 with little effort, so that the housing interior is easily accessible for repair purposes, for example.

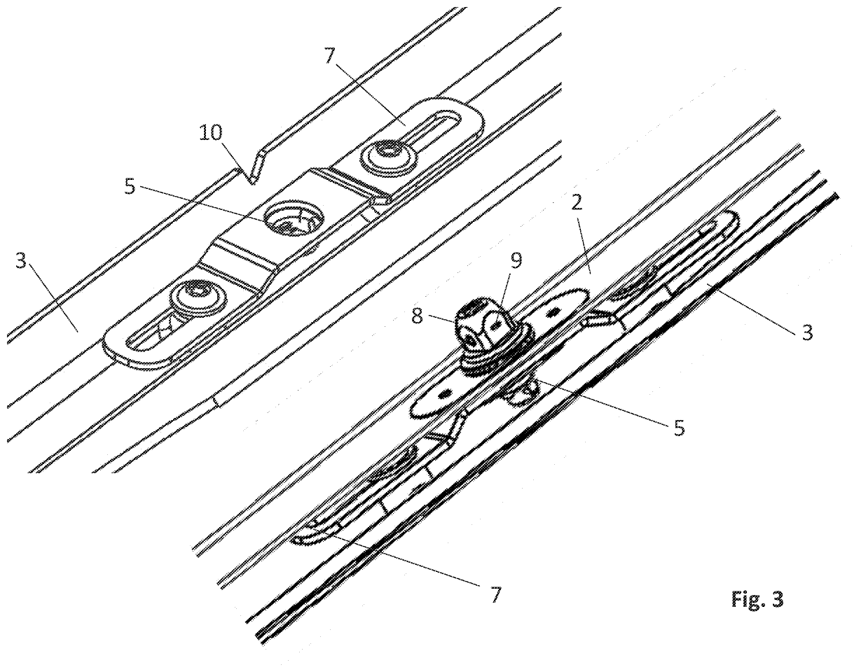

FIG. 3 shows in two perspective representations a possible configuration of the individual fasteners as quarter-turn fasteners. The upper illustration in FIG. 3 shows a fastening bar 7, which is screwed to the cover 3 at opposite ends. A retaining cam 5 for a quarter-turn fastener to be inserted therein is arranged in a central region of the fastening bar 7, which is configured to be at a distance from the cover 3 by corresponding shaping. The fastening bar 7 is screwed to the cover 3 via elongated holes, which enable the distance between the central region of the fastening bar 7 and the cover 3 to increase when there is a high tensile force on the retaining cam 5. Furthermore, the cover 3 has a notch 10 directly adjacent to the retaining cam 5, the effect of which will be discussed later.

In the lower illustration in FIG. 3, a quarter-turn fastener 8 arranged on the housing pan 2 is inserted into the retaining cam 5 of the fastening bar 7 that is fastened to the cover 3. Locking the quarter-turn fastener 8 in the retaining cam 5 causes the cover 3 to be fastened to the housing pan 2.

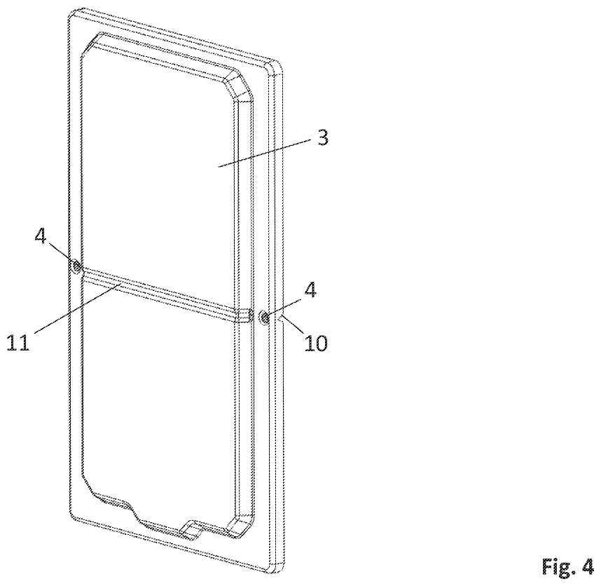

FIG. 4 shows an embodiment of a cover 2 of an explosion-proof housing according to the disclosure. Along a direct connecting line between the two individual fasteners 4, the cover 3 has an indentation 11 which can be introduced into the cover 3 during the shaping process. This indentation 11 as a structural element represents a deliberate weakening of the cover 3 in relation to a compressive force acting on the outer regions of the cover 3 from the inside of the housing in the assembled state of the cover 3 on the housing pan 2, as a result of which the cover bends or folds under such a force along a bending line essentially corresponding to the connecting line, and, as a result, even in the case of reduced explosion pressure, already forms a discharge gap between the cover 3 and the housing pan 2.

Alternatively or additionally, a notch 10 in the cover edge in the intersection region with the bending line and/or a reduced cover thickness in the region of the bending line can also be used as a structural element for a targeted weakening of the cover 3 in relation to bending along the bending line.

In the case in which two fasteners in each case are arranged on both opposite sides of the housing, and thereby two bending lines, each between the two fasteners assigned to the same outer region, are formed, for each bending line structural elements can be provided for weakening the cover with respect to bending. For those structural elements mentioned identical structural elements or even different structural elements can be provided.

What is claimed is:

1. A housing that is explosion-proof for a power electronics unit, comprising:
a housing pan, and
a cover that closes the housing pan via a seal, wherein edge regions of the housing pan and cover together form a first pair of opposing sides, and a second pair of opposing sides,
wherein the cover and the housing pan are pressed against each other only at one of the first pair or the second pair of opposing sides formed by the edge regions of the cover and the housing pan, via a plurality of fasteners that are configured to be released by rotation and that engage in latching structures, and
wherein the plurality of fasteners are arranged in a central third of the respective sides.

2. The housing according to claim 1, wherein on each side precisely one fastener is arranged in a middle of the side.

3. The housing according to claim 1, wherein two fasteners are arranged on at least one side.

4. The housing according to claim 1, wherein the fasteners are arranged releasably from the housing pan, and each of which engage in the latching structure which is arranged in or on the cover and is invisible from the side of the cover facing away from the housing pan.

5. The housing according to claim 4, wherein the latching structures are each arranged on a fastening bar which is fastened to the cover and which deforms in the event of a pressure rise in the housing interior such that a gap between the housing pan and the cover also forms in a region of the fasteners, through which gap the rising pressure can escape.

6. The housing according to claim 1, wherein the fasteners are configured as screws and the latching structures are configured as threads, wherein the screws engage through openings in the housing pan into the threads arranged in or on the cover.

7. The housing according to claim 1, wherein the fasteners are in each case configured as a quarter-turn fastener.

8. The housing according to claim 7, wherein the latching structure comprises a fastening bar, wherein the fastening bar is fastened to the cover at opposite ends and has a retaining cam in a central region for receiving the quarter-turn fastener in a latching manner.

9. The housing according to claim 7, wherein the quarter-turn fastener comprises a visually discernible indicator that shows a latching state of the quarter-turn fastener.

10. The housing according to claim 1, wherein the housing has two further sides that are shorter than the sides in which the fasteners are arranged.

11. The housing according to claim 1, wherein the cover has a structural element on a cover edge that reduces a force required for a bending of the cover along a bending line running between the fasteners, wherein the structural element comprises a notch on the cover edge, an indentation in the cover, or a reduced cover thickness in a region of the bending line.

12. A photovoltaic inverter comprising a housing, wherein the housing comprises:
a housing pan, and
a cover that closes the housing pan via a seal, wherein edge regions of the housing pan and cover together form a first pair of opposing sides, and a second pair of opposing sides,
wherein the cover and the housing pan are pressed against each other only at one of the first pair or the second pair of opposing sides formed by the edge regions of the cover and the housing pan, via a plurality of fasteners that are configured to be released by rotation and that engage in latching structures, and
wherein the plurality of fasteners are arranged in a central third of the respective sides.
